(19) United States
(12) Patent Application Publication
(10) Pub. No.: US 2016/0358939 A1
(43) Pub. Date: Dec. 8, 2016

(54) DISPLAY APPARATUS

(71) Applicant: Samsung Display Co., Ltd., Yongin-si (KR)

(72) Inventors: Seung Kyu LEE, Yongin-si (KR); Sung Jin MUN, Yongin-si (KR); Hyun Jae YOO, Yongin-si (KR); Sung Ryul KIM, Yongin-si (KR); Woo Sung SOHN, Yongin-si (KR); Jae Yong SHIN, Yongin-si (KR)

(21) Appl. No.: 14/997,800

(22) Filed: Jan. 18, 2016

(30) Foreign Application Priority Data
Jun. 2, 2015 (KR) 10-2015-0077865

(51) Int. Cl. H01L 27/12

(52) U.S. Cl. CPC H01L 27/124

(57) ABSTRACT

A display apparatus includes: a first substrate including a display area and a non-display area adjacent to the display area; a second substrate facing the first substrate; a display device disposed between the first substrate and the second substrate; and a fan-out line, disposed in the non-display area, to apply a display signal to the display device. The fan-out line includes: a first conductive layer; and a second conductive layer disposed on the first conductive layer, the second conductive layer being electrically connected to the first conductive layer. A width of the first conductive layer is different from a width of the second conductive layer.

### CROSS-REFERENCE TO RELATED APPLICATION

This application claims priority from and the benefit of Korean Patent Application No. 10-2015-0077865, filed on Jun. 2, 2015, which is hereby incorporated by reference for all purposes as if fully set forth herein.

### BACKGROUND

Field

Exemplary embodiments relate to a display apparatus.

Discussion of the Background

In general, a display apparatus displays images by driving a plurality of display devices disposed between two substrates. The display apparatus includes the display devices, and the display devices may be connected to a plurality of thin film transistors, respectively.

The thin film transistors are disposed on at least one of the two substrates. Each of the thin film transistors is connected to a gate line and a data line. Gate lines and data lines to which thin film transistors are connected may be connected to an external circuit through fan-out lines.

The fan-out lines have different lengths according to positions thereof, and therefore, a difference in resistance between at least two of the fan-out lines may occur. A signal transmission delay (RC delay) difference between at least two of the fan-out lines occurs due to the difference in resistance between the at least two of the fan-out lines. The signal transmission delay (RC delay) difference causes a deterioration of the display quality of the display apparatus.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments disclose a display apparatus in which the difference in resistance between fan-out lines is reduced or eliminated. According to an exemplary embodiment, a problematic disposition of a protective layer on multi-layered fan-out lines may be prevented or reduced.

Additional aspects will be set forth in the detailed description which follows, and, in part, will be apparent from the disclosure, or may be learned by practice of the inventive concept

An exemplary embodiment discloses a display apparatus including: a first substrate including a display area and a non-display area adjacent to the display area; a second substrate facing the first substrate; a display device disposed between the first substrate and the second substrate; and a fan-out line, disposed in the non-display area, to apply a display signal to the display device. The fan-out line includes: a first conductive layer; and a second conductive layer disposed on the first conductive layer, the second conductive layer being electrically connected to the first conductive layer. A width of the first conductive layer is different from a width of the second conductive layer.

An exemplary embodiment also discloses a display apparatus including: a first substrate including a display area and a non-display area adjacent to the display area, the display area including a pixel area; a gate line connected to a thin film transistor in the pixel area; a data line connected to the thin film transistor and insulated from the gate line; a display device connected to the thin film transistor; a second substrate facing the first substrate; a gate fan-out line disposed in the non-display area, the gate fan-out line being connected to the gate line; and a data fan-out line disposed in the non-display area, the data fan-out line being connected to the data line. At least one of the gate fan-out line and the data fan-out line includes: a first conductive layer; and a second conductive layer disposed on the first conductive layer, the second conductive layer being electrically connected to the first conductive layer. A width of one of the first and second conductive layers is greater than a width of the other one of the first and second conductive layers.

An exemplary embodiment further discloses a display apparatus including: a first substrate; a first conductive line pattern disposed on the first substrate, the first conductive line pattern including a gate electrode, a gate line connected to the gate electrode, at least a portion of a gate fan-out line connected to the gate line, and a lower layer of a data fan-out line; an insulating layer disposed on the first conductive line pattern; a semiconductor layer pattern disposed on the insulating layer, the semiconductor layer pattern including a channel portion overlapping the gate electrode to form a channel of a thin film transistor; a second conductive line pattern disposed on at least one of the semiconductor layer pattern and the insulating layer, the second conductive line pattern including a drain electrode, a source electrode, a data line connected to the source electrode, and an upper layer of the data fan-out line connected to the data line; a protective layer disposed on the second conductive pattern; a second substrate facing the first substrate; and a display device disposed between the first substrate and the second substrate. The upper layer of the data fan-out line is electrically connected to the lower layer of the data fan-out line, and a width of the upper layer of the data fan-out line is different from a width of the lower layer of the data fan-out line.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan view illustrating a display apparatus according to an exemplary embodiment.

FIG. 2 is an enlarged view of area EA1 of FIG. 1 according to an exemplary embodiment.

FIG. 3 is a cross-sectional view taken along section line I-I′ of FIG. 2 according to an exemplary embodiment.

FIG. 4 is an enlarged view of area EA2 of FIG. 1 according to an exemplary embodiment.

FIG. 5 and FIG. 6 are cross-sectional views taken along section line II-II′ of FIG. 4 according to an exemplary embodiment.

FIG. 7 is a sectional view taken along section line III-III′ of FIG. 4 according to an exemplary embodiment.

FIG. 8, FIG. 9, FIG. 10, and FIG. 11 are process sectional views taken along section line I-I′ of FIG. 2 according to an exemplary embodiment.

FIG. 12, FIG. 13, FIG. 14, and FIG. 15 are process sectional views taken along section line II-II′ of FIG. 4 according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

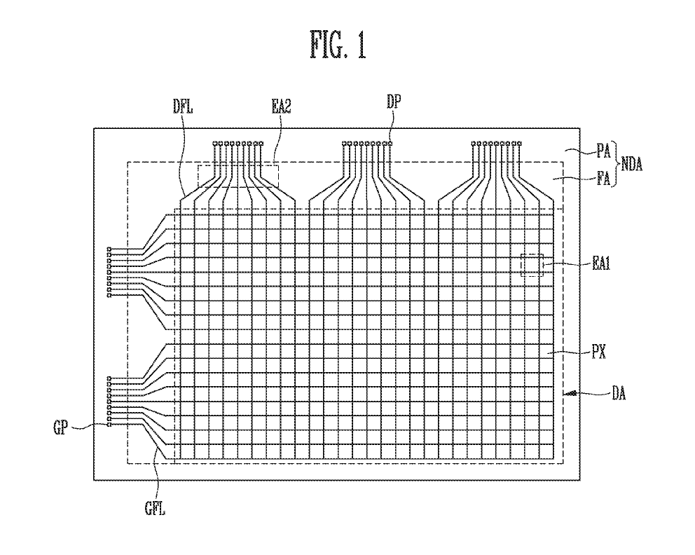

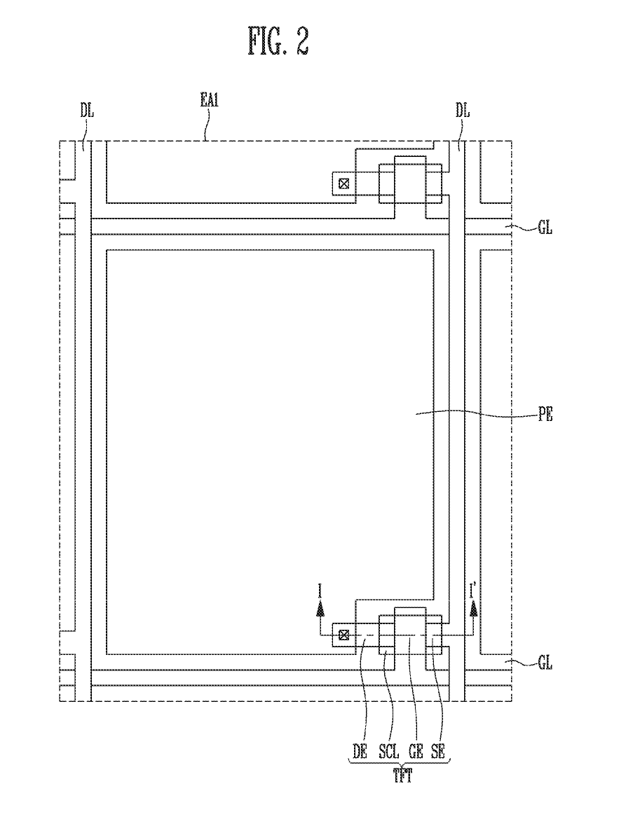

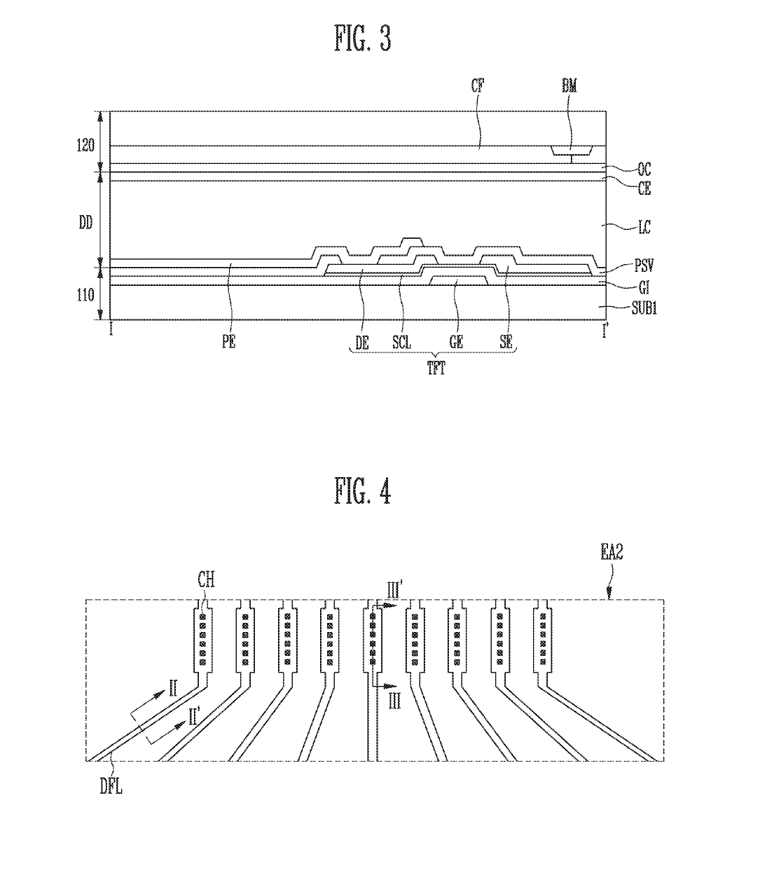

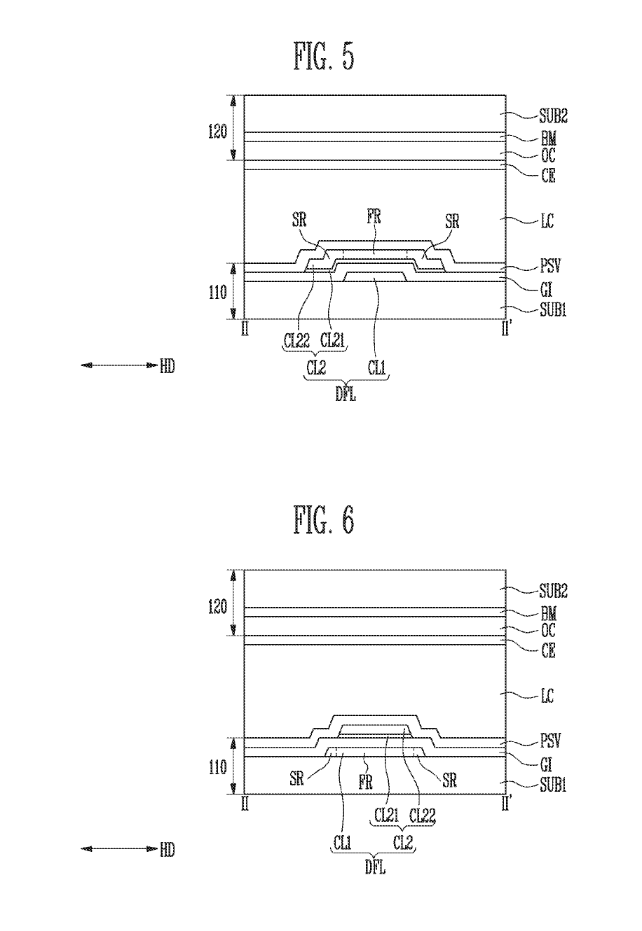

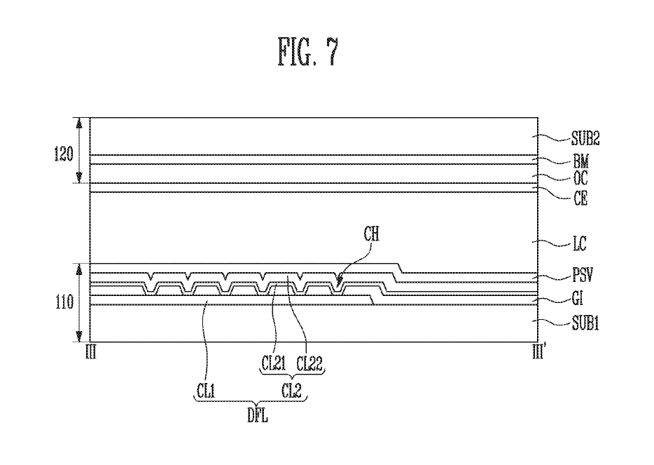

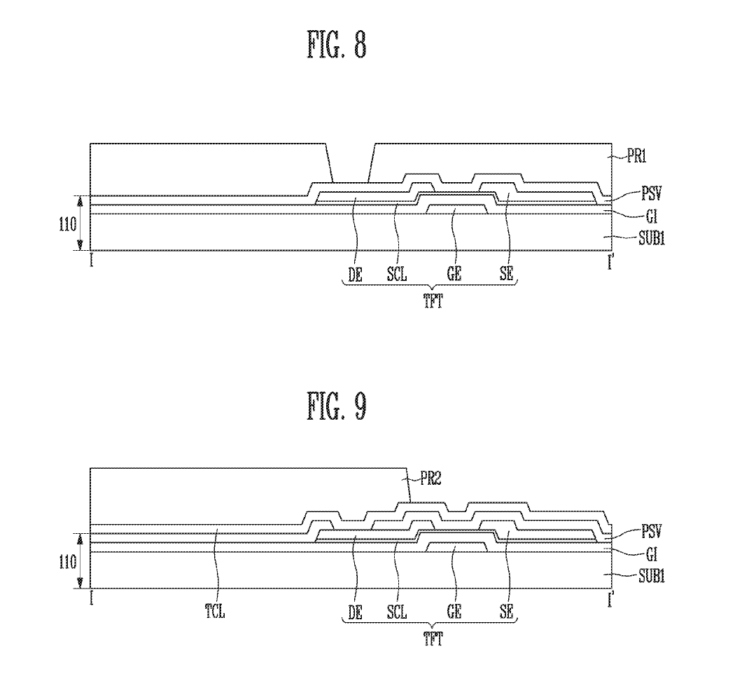

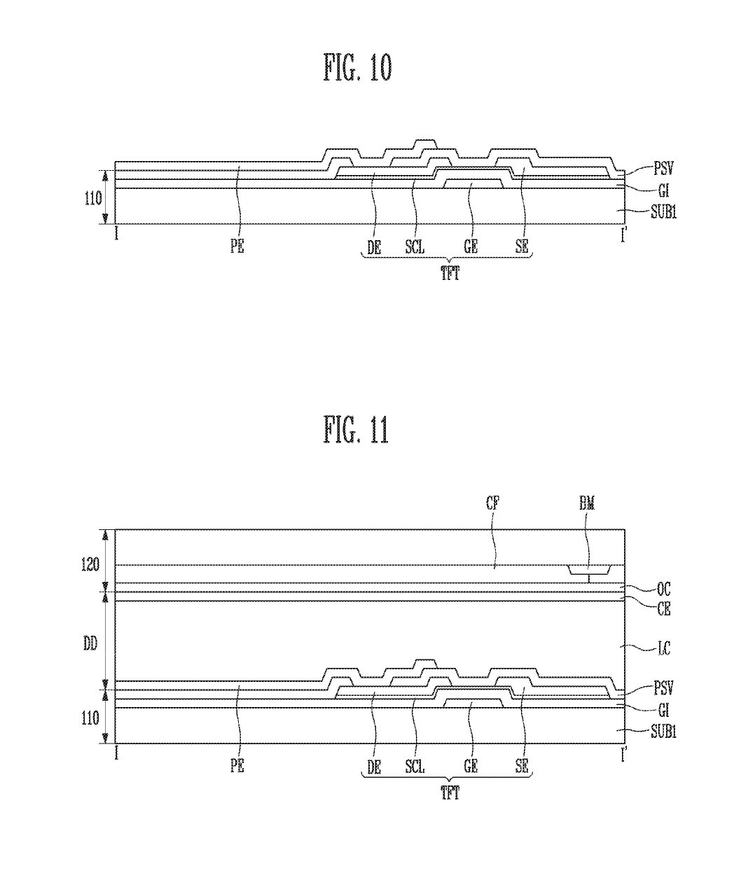

FIG. 1 is a plan view illustrating a display apparatus according to an exemplary embodiment. FIG. 2 is an enlarged view of area EA1 of FIG. 1 according to an exemplary embodiment. FIG. 3 is a cross-sectional view taken along section line I-I′ of FIG. 2 according to an exemplary embodiment. FIG. 4 is an enlarged view of area EA2 of FIG. 1 according to an exemplary embodiment. FIG. 5 and FIG. 6 are cross-sectional views taken along section line II-II′ of FIG. 4 according to an exemplary embodiment. FIG. 7 is a cross-sectional view taken along section line III-III′ of FIG. 4 according to an exemplary embodiment.

Referring to FIG. 1 through FIG. 7, the display apparatus may include a display area DA in which images are displayed and a non-display area NDA disposed adjacent to the display area DA. The display area DA may include a plurality of pixel areas PX. The pixel areas PX may be defined by a plurality of gate lines GL through which a scan signal among display signals is applied and a plurality of data lines DL through which a data signal among the display signals is applied. Each of the pixel areas PX may be disposed between two adjacent gate lines and between two adjacent data lines. The non-display area NDA may include a fan-out area FA adjacent to the display area DA and a pad area PA disposed at the outside of the fan-out area FA.

The display device may include a first substrate 110, a second substrate 120 facing the first substrate 110, and a display device DD disposed between the first substrate 110 and the second substrate 120.

The first substrate 110 may include a first base substrate SUB1 and at least one thin film transistor TFT disposed in each pixel area PX. The thin film transistor TFT may be connected to one of the gate lines GL and one of the data lines DL. Also, the thin film transistor TFT may be connected to the display device DD. Specifically, a gate electrode GE of the thin film transistor TFT may be connected to one of the gate lines GL, a source electrode SE of the thin film transistor TFT may be connected to one of the data lines DL, and a drain electrode DE of the thin film transistor TFT may be connected to a pixel electrode PE.

The first base substrate SUB1 may include a transparent insulating material, so that light can be transmitted therethrough. The first base substrate SUB1 may be a rigid substrate. For example, the first base substrate SUB1 may be one of a glass base substrate, a quartz base substrate, a glass ceramic base substrate, and a crystalline glass base substrate.

According to an exemplary embodiment, the first base substrate SUB1 may be a flexible substrate. For example, the first base substrate SUB1 may be one of a film base substrate and a plastic base substrate, including a polymer organic material. More specifically, the first base substrate SUB1 may include one of polyethersulfone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), triacetate cellulose (TAC), and cellulose acetate propionate (CAP). The first base substrate SUB1 may include fiber glass reinforced plastic (FRP).

A material applied to the first base substrate SUB1 preferably has resistance (or heat resistance) against a high processing temperature in a fabrication process of the display apparatus.

The thin film transistor TFT may include the gate electrode GE, a semiconductor layer SCL, a gate insulating layer GI insulating the gate electrode GE and the semiconductor layer SCL from each other, the source electrode SE, and the drain electrode DE.

The gate electrode GE may be disposed on the first base substrate SUB1. The gate electrode GE may be connected to one of the gate lines GL. An insulating layer (not shown) may be disposed between the first base substrate SUB1 and the gate line GL and between the first base substrate SUB1 and the gate electrode GE.

The gate insulating layer GI may be disposed over the gate line GL and the gate electrode GE. More specifically, the gate insulating layer GI may be disposed between the semiconductor layer SCL and the gate line GL and between the semiconductor layer SCL and the gate electrode GE. The gate insulating layer GI may include at least one of a silicon oxide (SiO_{X}) and a silicon nitride (SiN_{X}) layer. For example, the gate insulating layer GI may have a structure in which the silicon oxide layer and the silicon nitride layer are stacked.

The semiconductor layer SCL may be disposed on the gate insulating layer GI, and at least one portion of the semiconductor layer SCL may overlap the gate electrode GE. The semiconductor layer SCL may include one of amorphous silicon (a-Si), polycrystalline silicon (p-Si), and semiconductor oxide. In the semiconductor layer SCL, regions connected to the source electrode SE and the drain electrode DE may be, respectively, source and drain regions doped or implanted with impurities. A region between the source and drain regions may be a channel region. Here, the semiconductor oxide may include at least one of Zn, In, Ga, Sn, and a mixture thereof. For example, the semiconductor oxide may include indium-gallium-zinc oxide (IGZO).

One end of the source electrode SE may be connected to the data line DL intersecting the gate line GL. For example, the source electrode SE may be connected to a protruding portion of the data line DL. The other end of the source electrode SE may be connected to one end of the semiconductor layer SCL.

The drain electrode DE may be disposed to be spaced apart from the source electrode SE. One end of the drain electrode DE may be connected to the other end of the semiconductor layer SCL. The other end of the drain electrode DE may be connected to the display device DD.

It is described as an example that the thin film transistor TFT is a thin film transistor of a bottom gate structure in which the gate electrode GE of the thin film transistor TFT is disposed under the semiconductor layer SCL. However, aspects of an exemplary embodiment are not limited thereto. For example, the thin film transistor TFT may be a thin film transistor of a top gate structure in which the gate electrode GE is disposed above the semiconductor layer SCL.

The first substrate 110 may further include a protective layer PSV disposed over the thin film transistor TFT. The protective layer PSV covers the thin film transistor TFT, and may expose the other end of the drain electrode DE.

The protective layer PSV may include at least one of an inorganic protective layer and an organic protective layer. For example, the protective layer PSV may include an inorganic protective layer covering the thin film transistor TFT and an organic protective layer disposed on the inorganic protective layer.

The inorganic protective layer may include at least one of silicon oxide (SiO_{X}) and silicon nitride (SiN_{X}). For example, the inorganic protective layer may include a first inorganic protective layer covering the thin film transistor TFT and a second inorganic protective layer disposed on the first inorganic protective layer. The first inorganic protective layer may include the silicon oxide, and the second inorganic protective layer may include the silicon nitride, but aspects are not limited as such.

The organic protective layer may include an organic insulating material through which light can be transmitted. For example, the organic protective layer may include at least one of polyacrylates resin, epoxy resin, phenolic resin, polyamides resin, polyimides resin, unsaturated polyesters resin, poly-phenylenethers resin, poly-phenylene sulfides resin, and benzocyclobutene resin.

In the fan-out area FA, a plurality of gate fan-out lines GFL and a plurality of data fan-out lines DFL may be disposed on the first base substrate SUB1. The gate fan-out lines GFL may be connected to the gate lines GL, respectively. The data fan-out lines DFL may be connected to the data lines DL, respectively.

At least one of the gate fan-out lines GFL and the data fan-out lines DFL, for example, each of the data fan-out lines DFL, may include a first conductive layer CL1 and a second conductive layer CL2 disposed over the first conductive layer CL1. Both the first conductive layer CL1 and the second conductive layer CL2 of the data fan-out lines DFL may be connected to data pads DP to reduce resistance. Both the first conductive layer CL1 and the second conductive layer CL2 of the gate fan-out lines GFL may be connected to gate pads GP to reduce resistance.

The gate insulating layer GI may be disposed between the first conductive layer CL1 and the second conductive layer CL2. The gate insulating layer GI may include at least one contact hole CH through which the first conductive layer CL1 is exposed.

The first conductive layer CL1 may be disposed on the same plane as the gate line GL and the gate electrode GE. The first conductive layer CL1 may include the same material as the gate line GL and the gate electrode GE. More specifically, the first conductive layer CL1 may be disposed on the first base substrate SUB1 in the fan-out area FA.

The second conductive layer CL2 may be connected to the first conductive layer CL1 through the contact hole CH. The second conductive layer CL2 may be electrically connected to the first conductive layer CL1 since both layers include conductive materials. Since the first and second conductive layers CL1 and CL2 are connected to each other, resistances of the data fan-out lines DFL decreases, and thus the difference in resistance between the data fan-out lines DFL can be decreased. Further, since the difference in resistance between the data fan-out lines DFL decreases, a signal transmission delay (RC delay) difference between the data fan-out lines DFL also decreases. The decrease in the signal transmission delay (RC delay) difference can improve the display quality of the display apparatus.

The second conductive layer CL2 may include a first layer CL21 and a second layer CL22 disposed on the first layer CL21. The first layer CL21 may include the same material as the semiconductor layer SCL. The first layer CL21 may be doped or implanted with impurities to have conductivity. The second layer CL22 may include the same material as the data line DL, the source electrode SE, and the drain electrode DE. The second layer CL22 may be electrically connected to the first conductive layer CL1 through the at least one contact hole CH. Further, the first layer CL21 or the second layer CL22 may directly contact the first conductive layer CL1 through the at least one contact hole CH. The first layer CL21 and the semiconductor layer SCL may be formed by patterning the same layer and may be patterned with one mask. The second layer CL22 and the data line DL may be formed by patterning the same conductive layer.

The width of one of the first and second conductive layers CL1 and CL2 may be greater than the width of the other of the first and second conductive layers CL1 and CL2. The widths of the first and second conductive layers CL1 and CL2 are measured along a direction perpendicular to the longitudinal direction of the data fan-out lines DFL. For example, as shown in FIG. 5 and FIG. 6, the widths of the first and second conductive layers CL1 and CL2 are measured along a horizontal direction HD shown in FIG. 5 and FIG. 6.

For example, as shown in FIG. 5, the width of the second conductive layer CL2 may be greater than the width of the first conductive layer CL1. Here, the second conductive layer CL2 may include a first region FR overlapping the first conductive layer CL1 and a second region SR extending from at least one of both sides of the first region FR. The second conductive layer CL2 may include two second regions SR respectively extending from both sides of the first region FR.

As shown in FIG. 6, the width of the first conductive layer CL1 may be greater than the width of the second conductive layer CL2. Here, the first conductive layer CL1 may include a first region FR overlapping the second conductive layer CL2 and a second region SR extending from at least one of both sides of the first region FR. The first conductive layer CL1 may include two second regions SR respectively extending from both sides of the first region FR.

Since the width of one of the first and second conductive layers CL1 and CL2 is greater than the width of the other of the first and second conductive layers CL1 and CL2, the data fan-out lines DFL may have a small step difference as compared with a step difference formed when the widths of the first and second conductive layers CL1 and CL2 are equal to each other.

In the pad area PA, a plurality of gate pads GP and a plurality of data pads DP may be disposed on the first base substrate SUB1. For example, as shown in FIG. 1, the gate pads GP may be disposed on a first side, e.g., the left side of the display area DA, and the data pads DP may be disposed on a second side, e.g., the top side of the display area DA. The gate pads GP may connect the gate fan-out lines GFL to a gate driving circuit (not shown), and the data pads DP may connect the data fan-out lines DFL to a data driving circuit (not shown).

The second substrate 120 may be an opposite substrate facing the first substrate 110. The second substrate 120 may include a second base substrate SUB2, a light blocking pattern BM, a color filter CF, and an overcoat layer OC. However, at least one of the light blocking pattern BM, the color filter CF, and the overcoat layer OC may be disposed on the first substrate 110.

The second base substrate SUB2 may include the same material as the first base substrate SUB1. For example, the second base substrate SUB2 a rigid substrate or a flexible substrate.

The light blocking pattern BM may be disposed on a surface of the second base substrate SUB2, facing the first substrate 110. The light blocking pattern BM may be disposed corresponding to the boundary between the pixel areas PX. The light blocking pattern BM can prevent light leakage caused by misalignment of liquid crystal molecules.

The color filter CF may have one of red, green, blue, cyan, magenta, and yellow colors. The color filter CF may be disposed corresponding to the pixel areas PX. According to an exemplary embodiment, it is described as an example that the color filter CF is included in the second substrate 120. However, as noted above, the color filter CF may be disposed on the first substrate 110.

The overcoat layer OC covers the color filter CF, and reduces a step difference caused by the light blocking pattern BM and the color filter CF.

The display device DD is disposed between the first and second substrates 110 and 120, and may be connected to the drain electrode DE. The display device DD may be any one of a liquid crystal display (LCD) device, an electrophoretic display (EPD) device, an electrowetting display (EWD) device, and an organic light emitting display (OLED) device. According to an exemplary embodiment, it is described as an example that, for convenience of illustration, the LCD device is illustrated as the display device DD. Although not shown in the figures, the display device may be configured to display images by using light provided from a backlight unit or light emitted through other configurations. For example, the OLED device may emit light without using the backlight unit.

The display device DD may include a first electrode PE, e.g., a pixel electrode PE, a second electrode CE, e.g., a common electrode CE, forming an electric field together with the first electrode PE, and an optical layer LC capable of allowing light to be transmitted by the electric field or blocking light, e.g., capable of allowing or blocking light based on alignment directions of liquid crystal molecules.

The first electrode PE may be disposed on the protective layer PSV, and connected to the other end of the drain electrode DE. The first electrode PE may include a transparent conductive oxide. For example, the first electrode PE may include at least one of indium tin oxide (ITO), indium zinc oxide (IZO), aluminum zinc oxide (AZO), gallium doped zinc oxide (GZO), zinc tin oxide (ZTO), gallium tin oxide (GTO), and fluorine doped tin oxide (FTO).

The second electrode CE may be insulated from the first electrode PE. The second electrode CE may include the same material as the first electrode PE. The second electrode CE may receive a common voltage applied from the outside. The second electrode CE may be disposed on the overcoat layer OC of the second substrate 120 such that the second electrode CE and the first electrode PE form an electric field on the optical layer LC of the display device DD.

The optical layer LC may include a plurality of liquid crystal molecules if the optical layer LC includes a liquid crystal layer. The liquid crystal molecules are aligned in a specific direction by an electric field formed by the first and second electrodes PE and CE, to adjust the transmittance of light. Thus, the optical layer LC allows light provided from the backlight unit to be transmitted therethrough and controls the light transmission for each pixel, so that the display apparatus can display intended images.

According to an exemplary embodiment, it is described as an example that the display device DD has a structure including the first electrode PE, the second electrode CE, and the optical layer LC disposed between the first and second electrodes PE and CE. However, aspects are not limited thereto. For example, the display device DD may have a structure in which the first and second electrodes PE and CE are disposed on the first substrate 110, and the optical layer LC is disposed between the first and second electrodes PE and CE and the second substrate 120 facing the first substrate 110. Here, at least one of the first and second electrodes PE and CE may include a plurality of slits.

Further, as shown in FIG. 1 and FIG. 4, gate fan-out lines GFL and data fan-out lines DFL have different lengths because widths of extended portions of the gate lines GL and data lines DL become narrower to be connected gate pads GP and data pads DP, respectively. Thus, the different lengths cause different resistances between gate lines GL and between data lines DL. In order to reduce the difference of resistances, the number of contact holes CH may be differently formed. For example, the center data fan-out line DFL illustrated in FIG. 4 may have fewer contact holes CH than at least one other data fan-out line DFL illustrated in FIG. 4. Further, the width and/or length of the first conductive layers CL1 of the center data fan-out line DFL and may be different from the width and/or length of the first conductive layers CL1 of at least one other data fan-out line DFL.

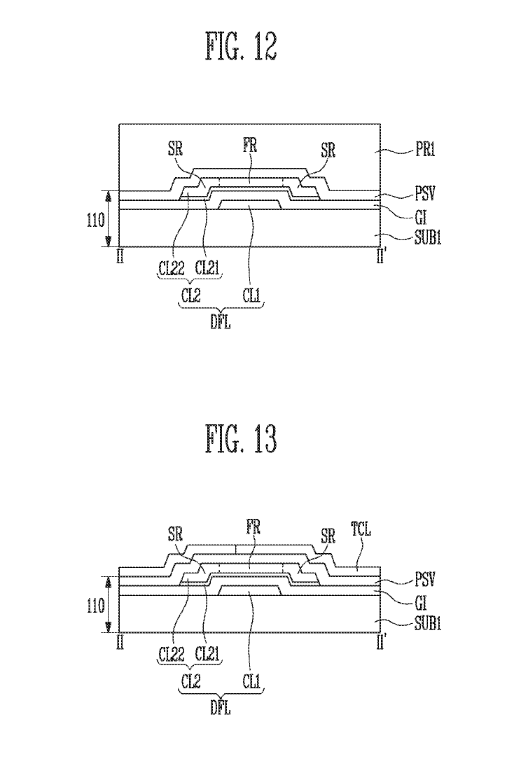

Hereinafter, a fabrication method of the display apparatus shown in FIG. 1 through FIG. 7 will be described with reference to FIG. 8 through FIG. 15.

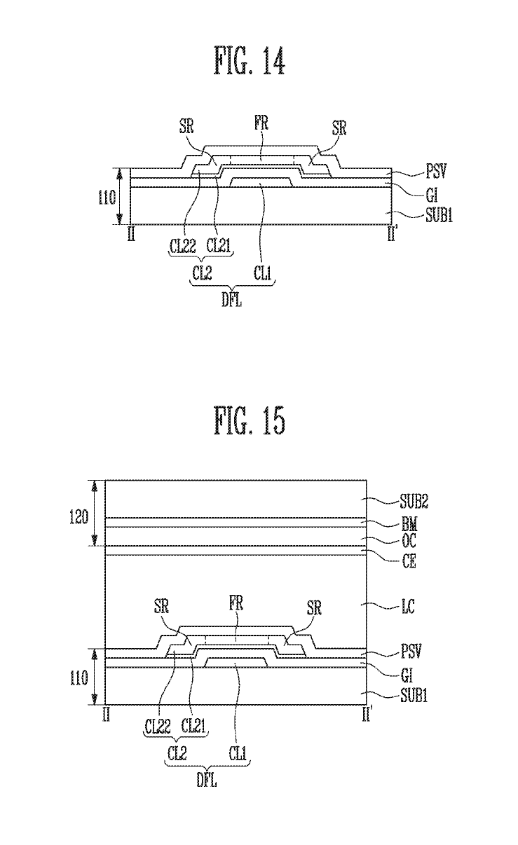

FIG. 8 through FIG. 11 are process sectional views taken along section line I-I′ of FIG. 2 according to an exemplary embodiment. FIG. 12 through FIG. 15 are process sectional views taken along section line II-II′ of FIG. 4 according to an exemplary embodiment.

Referring to FIGS. 8 and 12, a first base substrate SUB1 including a display area DA and a non-display area NDA is prepared. The display area DA may include a plurality of pixel areas PX. The non-display area NDA may include a fan-out area FA adjacent to the display area DA and a pad area PA at the outside of the fan-out area FA. The first base substrate SUB1 may be a flexible substrate or a rigid substrate.

In each pixel area PX, a thin film transistor TFT may be formed on the first base substrate SUB1. The thin film transistor TFT may include a gate electrode GE, a semiconductor layer SCL, a source electrode SE, and a drain electrode DE.

At the same time when the thin film transistor TFT is formed, gate fan-out lines GFL and data fan-out lines DFL may be formed in the non-display area NDA.

For example, the thin film transistor TFT, the gate fan-out lines GFL, and the data fan-out lines DFL may be formed as follows.

First, a first conductive layer is formed by coating a conductive material on the first base substrate SUB1 and then patterned, thereby forming a gate conductive layer. The gate conductive layer may include gate lines GL disposed between pixel areas PX adjacent to each other, gate electrodes GE connected to one of the gate lines GL, the gate electrodes GE each being disposed in a corresponding one of the pixel areas PX, the gate fan-out lines GFL respectively connected to the gate lines GL and disposed at one side of the fan-out area FA, gate pads GP respectively connected to the gate fan-out lines GFL in the pad area PA, and first conductive layers CL1 of the data fan-out lines DFL at the other side of the fan-out area FA.

After the gate conductive layer is formed, a gate insulating layer GI covering the gate conductive layer may be formed. The gate insulating layer GI may include at least one of silicon oxide (SiO_{X}) and silicon nitride (SiN_{X}). For example, the gate insulating layer GI may include a first gate insulating layer disposed on the gate conductive layer and a second gate insulating layer disposed on the first gate insulating layer. The first gate insulating layer may include the silicon oxide, and the second gate insulating layer may include the silicon nitride.

After the gate insulating layer GI is formed, at least one contact hole CH exposing the first conductive layer CL1 may be formed by patterning the gate insulating layer GI.

After the contact hole CH is formed, a semiconductor layer SCL including a semiconductor material may be formed on the gate insulating layer GI. The semiconductor layer SCL may include one of amorphous silicon (a-Si), polycrystalline silicon (p-Si), and semiconductor oxide.

After the semiconductor layer SCL is formed, a second conductive layer may be formed by coating a conductive material on the semiconductor layer SCL. Then, the second conductive layer is patterned, thereby forming a data conductive layer. The data conductive layer may include data lines DL disposed between pixel areas PX adjacent to each other, source electrodes SE extending from one of the data lines DL, the source electrodes SE each connected to one end of the semiconductor layer SCL of a corresponding one of the thin film transistors TFT, drain electrodes DE connected to the other end of the semiconductor layer SCL of the corresponding one of the thin film transistors TFT, second conductive layers CL2 of the data fan-out lines DFL, disposed on the first conductive layer CL1 at the other side of the fan-out area FA, and data pads DP respectively connected to the second conductive layers CL2 in the pad area PA. The data lines DL intersect the gate lines GL and are insulated from the gate lines GL by the gate insulating layer GI.

According to the above processes, the first substrate 110 may be formed, which includes the first base substrate SUB1, a plurality of gate lines GL disposed on the first base substrate SUB, a plurality of data lines DL intersecting the gate lines GL, thin film transistors TFT respectively connected to the gate lines GL and the data lines DL, gate fan-out lines GFL respectively connected to the gate lines GL, data fan-out lines DFL respectively connected to the data lines DL, gate pads GP respectively connected to the gate fan-out lines GFL, and data pads DP respectively connected to the data fan-out lines DFL.

The thin film transistors TFT may be formed, each of which is connected to one of the gate lines GL and one of the data lines DL. The gate fan-out lines GFL and the data fan-out lines DFL may be formed together with the thin film transistors TFT.

The data fan-out lines DFL may include the first conductive layer CL1 and the second conductive layer CL2. The second conductive layer CL2 may be connected to the first conductive layer CL1 through the contact hole CH. Since the first and second conductive layers CL1 and CL2 are connected to each other, resistances of the data fan-out lines DFL may be decreased in comparison with a different data fan-out line, which includes only one conductive layer.

The second conductive layer CL2 may include a first layer CL21 and a second layer CL22 disposed on the first layer CL21. The first layer CL21 may include the same material as the semiconductor layer SCL. The first layer CL21 may be doped or implanted with impurities to have conductivity. The second layer CL22 may include the same material as the data line DL, the source electrode SE, and the drain electrode DE.

The width of one of the first and second conductive layers CL1 and CL2 may be greater than the width of the other one of the first and second conductive layers CL1 and CL2. For example, the width of the second conductive layer CL2 may be greater than the width of the first conductive layer CL1. In such a configuration, the second conductive layer CL2 may include a first region FR overlapping the first conductive layer CL1 and a second region SR extending from at least one of both sides of the first region FR. The second conductive layer CL2 may include two second regions SR respectively extending from both sides of the first region FR.

Since the width of one of the first and second conductive layers CL1 and CL2 is greater than the width of the other one of the first and second conductive layers CL1 and CL2, the data fan-out lines DFL may have a small step difference in comparison with a step difference formed when the widths of the first and second conductive layers CL1 and CL2 are equal to each other.

After the data conductive layer is formed, a protective layer PSV covering the data conductive layer may be formed. Thus, the protective layer PSV may cover the first substrate 110. The protective layer PSV may include at least one of an inorganic protective layer and an organic protective layer. For example, the protective layer PSV may include an inorganic protective layer covering the data conductive layer and an organic protective layer disposed on the inorganic protective layer.

After the protective layer PSV is formed, a first photoresist pattern PR1 may be formed over the protective layer PSV. The first photoresist pattern PR1 may be formed by forming a first photoresist material layer by coating a photoresist material on the protective layer PSV and then exposing and developing the first photoresist material layer. Here, the first photoresist pattern PR1 may include an opening overlapping a portion of the drain electrode DE.

If the widths of the first and second conductive layers CL1 and CL2 are equal to each other, the data fan-out lines DFL have a large step difference, and a coating defect of the first photoresist material layer may occur at a side portion of the data fan-out lines DFL. However, according to an exemplary embodiment, if the width of one of the first and second conductive layers CL1 and CL2 is greater than the width of the other one of the first and second conductive layers CL1 and CL2, the data fan-out lines DFL have a small step difference. Thus, it is possible to prevent an occurrence of a coating defect of the first photoresist material layer at the side portion of the data fan-out lines DFL.

Referring to FIG. 9 and FIG. 13, after the first photoresist pattern PR1 is formed, the protective layer PSV is patterned through an etching process. The protective layer PSV may allow a portion of the top surface of the drain electrode DE to be exposed by the patterning of the protective layer PSV. The portion of the top surface of the drain electrode DE corresponds to the opening of the first photoresist pattern PR1.

Then, the first photoresist pattern PR1 is removed.

After the first photoresist pattern PR1 is removed, a transparent conductive layer TCL including a transparent conductive oxide may be formed on the protective layer PSV. The transparent conductive layer TCL may include at least one of indium tin oxide (ITO), indium zinc oxide (IZO), aluminum zinc oxide (AZO), gallium doped zinc oxide (GZO), zinc tin oxide (ZTO), gallium tin oxide (GTO), and fluorine doped tin oxide (FTO).

After the transparent conductive layer TCL is formed, a second photoresist pattern PR2 may be formed on the transparent conductive layer TCL as shown in FIG. 9. The second photoresist pattern PR2 exposes a portion of the transparent conductive layer TCL. However, the second photoresist pattern PR2 covers at least a portion of the transparent conductive layer TCL corresponding to the portion of the top surface of the drain electrode DE corresponding to the opening of the first photoresist pattern PR1, such that a first electrode PE shown in FIG. 10 electrically connects the drain electrode DE to a corresponding display device in the pixel.

The second photoresist pattern PR2 may be formed by forming a second photoresist material layer by coating a photoresist material on the transparent conductive layer TCL and then exposing and developing the second photoresist material layer. Here, the second photoresist pattern PR2 may include an opening overlapping a portion of the transparent conductive layer TCL.

If the widths of the first and second conductive layers CL1 and CL2 are equal to each other, the data fan-out lines DFL have a large step difference, and a coating defect of the second photoresist material layer may occur at a side portion of the data fan-out lines DFL. However, according to an exemplary embodiment, if the width of one of the first and second conductive layers CL1 and CL2 is greater than the width of the other one of the first and second conductive layers CL1 and CL2, the data fan-out lines DFL have a small step difference. Thus, it is possible to prevent an occurrence of a coating defect of the first photoresist material layer at the side portion of the data fan-out lines DFL.

Referring to FIG. 10 and FIG. 14, after the second photoresist pattern PR2 is formed, the transparent conductive layer TCL may be patterned through an etching process. The first electrode PE connected to the drain electrode DE may be formed by the patterning of the transparent conductive layer TCL.

Then, the second photoresist pattern PR2 is removed.

Referring to FIG. 11 and FIG. 15, after the second photoresist pattern PR2 is removed, an optical layer LC is disposed on the first electrode PE. The optical layer LC may be a liquid crystal layer including a plurality of liquid crystal molecules. The liquid crystal molecules are aligned in a specific direction by an electric field generated between the first electrode PE and the second electrode CE, so that the display apparatus can display images, using light provided from the outside, e.g., the backlight unit (not shown).

After the optical layer LC is disposed, a second substrate 120 facing the first substrate 110 is disposed on the optical layer LC. The second electrode CE forming, together with the first electrode PE, an electric field may be disposed on one surface of the second substrate 120.

The second substrate 120 may include a second base substrate SUB2, a light blocking pattern BM, a color filter CF, and an overcoat layer OC. The second base substrate SUB2 may include the same material as the first base substrate SUB1. The light blocking pattern BM may be disposed on a surface of the second base substrate SUB2, facing the first substrate 110. The light blocking pattern BM may be disposed on a location corresponding to the boundary between the pixel areas PX. The light blocking pattern BM can prevent or reduce light leakage caused by misalignment of the liquid crystal molecules. The color filter CF may have one of red, green, blue, cyan, magenta, and yellow colors. The color filter CF may be disposed on a location corresponding to the pixel area PX. The overcoat layer OC covers the color filter CF, and reduces a step difference caused by the light blocking pattern BM and the color filter CF.

The second electrode CE may be disposed on the overcoat layer OC. The second electrode CE may include the same material as the first electrode PE.

After the second substrate 120 is disposed on the optical layer LC, the first and second substrates 110 and 120 are joined together using a sealant (not shown). Thus, it is possible to fabricate a display apparatus including a first substrate 110, a second substrate 120 facing the first substrate 110, and a display device DD disposed between the first and second substrates 110 and 120.

The sealant (not shown) may be disposed in the non-display area NDA. The sealant can prevent the material of the optical layer LC from being leaked to the outside.

According to an exemplary embodiment, a display apparatus may include a first substrate, e.g., the first base substrate SUB1, a first conductive pattern disposed on the first substrate, an insulating layer disposed on the first conductive line pattern, a semiconductor layer pattern disposed on the insulating layer, a second conductive line pattern disposed on at least one of the semiconductor layer pattern and the insulating layer, a protective layer disposed on the second conductive pattern, a second substrate facing the first substrate, and a display device disposed between the first substrate and the second substrate.

The first conductive line pattern may include a gate electrode GE, a gate line GL connected to the gate electrode GE, at least a portion of a gate fan-out line GFL connected to the gate line GL, and a lower layer of a data fan-out line DFL. The at least a portion of the gate fan-out line GFL may include the first conductive layer CL1 of the gate fan-out line GFL. The gate fan-out line GFL may include the second conductive layer CL2 electrically connected to the first conductive layer CL1 of the gate fan-out line GFL through a contact hole CH of the insulating layer. The second conductive layer CL2 of the gate fan-out line GFL may be formed by patterning at least one of the semiconductor layer pattern and the second conductive line pattern. The lower layer of a data fan-out line DFL may be insulated from the other portions of the first conductive line pattern. The lower layer of the data fan-out line DFL may include the first conductive layer CL1 of the data fan-out line DFL.

The semiconductor layer pattern may include a channel portion overlapping the gate electrode to form a channel of a thin film transistor TFT. The semiconductor layer pattern may also include the first layer CL21 of the data fan-out line DFL and the first layer CL21 of the gate fan-out line GFL. The first layer CL21 of the data fan-out line DFL may be a middle layer of the data fan-out line DFL and contact the lower layer of the data fan-out line DFL through a contact hole CH of the insulating layer. The upper layer of the data fan-out line DFL, e.g., the second layer CL22 of the data fan-out line DFL, may be disposed on the middle layer of the data fan-out line DFL. However, according to an exemplary embodiment, the first layer CL21 of the data fan-out line DFL may be omitted, and the second layer CL22 of the data fan-out line DFL may directly contact the first conductive layer CL1 of the data fan-out line DFL. Similarly, the first layer CL21 of the gate fan-out line GFL may be omitted.

The second conductive line pattern may include a drain electrode DE, a source electrode SE, a data line DL connected to the source electrode SE, and an upper layer of the data fan-out line DFL connected to the data line DL. The upper layer of the data fan-out line DFL may include the second layer CL22 of the data fan-out line DFL. The second conductive line pattern may also include an upper layer of the gate fan-out line GFL, which is electrically connected to a lower layer of the gate fan-out line GFL.

The protective layer may be the protective layer PSV illustrated above, and the display device may be the display device DD illustrated above. The upper layer of the data fan-out line DFL may be electrically connected to the lower layer of the data fan-out line DFL through a contact hole CH of the insulating layer. Further, the width of the upper layer of the data fan-out line DFL may be different from the width of the lower layer of the data fan-out line DFL (see e.g., FIG. 5 and FIG. 6). As shown in FIG. 5 and FIG. 6, the different widths of the upper and lower layers of the data fan-out line DFL may create a plurality of smaller step portions on the protective layer PSV rather than having a bigger one step portion, which may cause a problematic disposition of the protective layer PSV. The structure reduces the size of a step difference of the fan-out line.

As described above, according to an exemplary embodiment, the fan-out line of the display apparatus, particularly the data fan-out line includes a first conductive layer and a second conductive layer connected to the first conductive layer, thereby reducing line resistance. Further, the width of one of the first and second conductive layers is greater than that of the other of the first and second conductive layers, thereby reducing a step difference of the fan-out line. Thus, it is possible to prevent a coating defect of an organic layer, which may occur at a side portion of the fan-out line.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A display apparatus comprising:
a first substrate comprising a display area and a non-display area adjacent to the display area;
a second substrate facing the first substrate;
a display device disposed between the first substrate and the second substrate; and
a fan-out line, disposed in the non-display area, to apply a display signal to the display device,
wherein the fan-out line comprises:
a first conductive layer; and
a second conductive layer disposed on the first conductive layer, the second conductive layer being electrically connected to the first conductive layer,
wherein a width of the first conductive layer is different from a width of the second conductive layer.

2. The display apparatus of claim 1, further comprising:
an insulating layer disposed between the first conductive layer and the second conductive layer, the insulating layer having at least one contact hole through which the first conductive layer is electrically connected to the second conductive layer.

3. The display apparatus of claim 2, wherein one of the first and second conductive layers comprises:
a first region overlapping the other one of the first and second conductive layers; and
a second region extending from at least one of both sides of the first region.

4. The display apparatus of claim 3, wherein the one of the first and second conductive layers comprises two second regions respectively extending from both sides of the first region.

5. A display apparatus comprising:
a first substrate comprising a display area and a non-display area adjacent to the display area, the display area comprising a pixel area;
a gate line connected to a thin film transistor in the pixel area;
a data line connected to the thin film transistor and insulated from the gate line;
a display device connected to the thin film transistor;
a second substrate facing the first substrate;
a gate fan-out line disposed in the non-display area, the gate fan-out line being connected to the gate line; and
a data fan-out line disposed in the non-display area, the data fan-out line being connected to the data line,
wherein at least one of the gate fan-out line and the data fan-out line comprises:
a first conductive layer; and
a second conductive layer disposed on the first conductive layer, the second conductive layer being electrically connected to the first conductive layer,
wherein a width of one of the first and second conductive layers is greater than a width of the other one of the first and second conductive layers.

6. The display apparatus of claim 5, further comprising:
an insulating layer disposed between the first and second conductive layers, the insulating layer having at least one contact hole through which the first conductive layer is electrically connected to the second conductive layer.

7. The display apparatus of claim 6, wherein the first conductive layer and the gate line are disposed on a same plane.

8. The display apparatus of claim 7, wherein the second conductive layer and the data line comprise a same material.

9. The display apparatus of claim 8, wherein the width of the second conductive layer is greater than the width of the first conductive layer.

10. The display apparatus of claim 9, wherein the second conductive layer comprises:
a first region overlapping the first conductive layer; and
a second region extending from at least one of both sides of the first region.

11. The display apparatus of claim 10, wherein the second conductive layer comprises two second regions respectively extending from both sides of the first region.

12. The display apparatus of claim 8, wherein the width of the first conductive layer is greater than the width of the second conductive layer.

13. The display apparatus of claim 12, wherein the first conductive layer comprises:
a first region overlapping the second conductive layer; and
a second region extending from at least one of both sides of the first region.

14. The display apparatus of claim 13, wherein the first conductive layer comprises two second regions respectively extending from both sides of the first region.

15. The display apparatus of claim 8, wherein the thin film transistor comprises a gate electrode, a semiconductor layer, a gate insulating layer configured to insulate the gate electrode from the semiconductor layer, a source electrode, and a drain electrode, and
wherein the insulating layer comprises the gate insulating layer, and extends from the gate insulating layer that covers the gate electrode.

16. The display apparatus of claim 15, wherein the second conductive layer comprises:
a first layer disposed on the insulating layer; and
a second layer disposed on the first layer,
wherein the first layer and the semiconductor layer comprise a same material, and
wherein the second layer, the source electrode, and the drain electrode comprise a same material.

17. A display apparatus comprising:
a first substrate;
a first conductive line pattern disposed on the first substrate, the first conductive line pattern comprising a gate electrode, a gate line connected to the gate electrode, at least a portion of a gate fan-out line connected to the gate line, and a lower layer of a data fan-out line;
an insulating layer disposed on the first conductive line pattern;
a semiconductor layer pattern disposed on the insulating layer, the semiconductor layer pattern comprising a channel portion overlapping the gate electrode to form a channel of a thin film transistor;
a second conductive line pattern disposed on at least one of the semiconductor layer pattern and the insulating layer, the second conductive line pattern comprising a drain electrode, a source electrode, a data line connected to the source electrode, and an upper layer of the data fan-out line connected to the data line;
a protective layer disposed on the second conductive pattern;
is a second substrate facing the first substrate; and
a display device disposed between the first substrate and the second substrate,
wherein the upper layer of the data fan-out line is electrically connected to the lower layer of the data fan-out line, and
wherein a width of the upper layer of the data fan-out line is different from a width of the lower layer of the data fan-out line.

18. The display apparatus of claim 17, wherein the semiconductor layer pattern comprises a middle layer of the data fan-out line on which the upper layer of the data fan-out line is disposed.

19. The display apparatus of claim 18, wherein the middle layer of the data fan-out line contacts the lower layer of the data fan-out line through a contact hole of the insulating layer.

20. The display apparatus of claim 17, wherein the protective layer comprises a plurality of step portions formed by the different widths of the upper and lower layers of the data fan-out line.
